(19) United States
(12) Patent Application Publication
(10) Pub. No.: US 2013/0265045 A1
(43) Pub. Date: Oct. 10, 2013

(54) SYSTEM AND METHOD FOR MULTISTATION IMAGE PASTING FOR WHOLE BODY DIFFUSION-WEIGHTED IMAGING

(71) Applicant: Dan Xu, Oconomowoc, WI (US)

(72) Inventor: Dan Xu, Oconomowoc, WI (US)

(21) Appl. No.: 13/441,047

(22) Filed: Apr. 6, 2012

(51) Int. Cl. G01R 33/48; G01R 33/341

(52) U.S. Cl. 324/309; 324/322

(57) ABSTRACT

An MRI system includes a plurality of gradient coils positioned about a bore of a magnet, an RF transceiver system and an RF switch controlled by a pulse module to transmit RF signals to an RF coil assembly to acquire MR images, and a computer programmed to execute a diffusion-weighted imaging pulse sequence to acquire MR data from a subject over two or more stations, acquire imaging data of the subject over the two or more stations, reconstruct images that correspond to each of the two or more stations, and calculate an average intensity signal per slice within each of the reconstructed images. The computer is further programmed to adjust intensity within at least one of the reconstructed images based on the calculated average intensity signal within each of the reconstructed images and form a pasted image using a reconstructed image having its intensity adjusted and another reconstructed image.

### BACKGROUND OF THE INVENTION

Embodiments of the invention relate generally to magnetic resonance (MR) imaging and, more particularly, to correcting image pasting in diffusion-weighted echo planar imaging (EPI).

When a substance such as human tissue is subjected to a uniform magnetic field (polarizing field B0), the individual magnetic moments of the spins in the tissue attempt to align with this polarizing field, but precess about it in random order at their characteristic Larmor frequency. If the substance, or tissue, is subjected to a magnetic field (excitation field B1) which is in the x-y plane and which is near the Larmor frequency, the net aligned moment, or “longitudinal magnetization”, Mz, may be rotated, or “tipped”, into the x-y plane to produce a net transverse magnetic moment Mt. A signal is emitted by the excited spins after the excitation signal B1 is terminated and this signal may be received and processed to form an image.

When utilizing these signals to produce images, magnetic field gradients (Gx, Gy, and Gz) are employed. Typically, the region to be imaged is scanned by a sequence of measurement cycles in which these gradients vary according to the particular localization method being used. The resulting set of received NMR signals are digitized and processed to reconstruct the image using one of many well known reconstruction techniques.

Multistation whole body diffusion-weighted imaging (WB-DWI) is a known imaging technique that is based on EPI, which is often the method of choice due to its fast imaging sequence. However, EPI is prone to image artifacts and suffers from diffusion encoding direction dependent distortions due to residual eddy current fields and B0 inhomogeneity. These distortions, if not corrected, can lead to mis-registration among DW images of different directions and inaccuracies in post processing operations involving DW image combination.

Overall, EPI has been significantly improved in recent years with a number of pre-processing techniques that include applying high order eddy current (HOEC) generated magnetic field error correction during application of the WB-DWI pulse and also applying HOEC-generated magnetic field corrections during image reconstruction, as examples. However, despite the improvements, technical challenges still remain, which include 1) geometric discontinuities at station boundaries due to the different B0 offset field that different stations face, and the eddy current and B0 related image distortion, 2) intensity discontinuities between stations due to the sensitivity of RF pulses relative to B0 field offset and/or different transmit gain, and 3) image blurring or ghosting due to eddy current induced mis-registration.

HOEC and slice-dependent B0 offset compensation have reduced these problems to a degree. However, slight geometric and intensity discontinuities can still exist due to the residual eddy current and B0 inhomogeneity. Conventional, generic post processing software tends to handle these problems poorly because it does not build its model based upon the WB-DWI sequence (e.g., single shot echo planar imaging). For instance, known post-processing techniques can either miss modeling some of the image degradation (such as intensity variation) or miss geometric discontinuities (which can manifest itself as an image shift in the phase encoding direction).

It would therefore be desirable to have a system and method capable of correcting geometric and intensity discontinuities due to residual eddy current and B0 inhomogeneity.

### BRIEF DESCRIPTION OF THE INVENTION

According to an aspect of the invention, an MRI apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images, and a computer programmed to execute a diffusion-weighted imaging pulse sequence to acquire MR data from a subject over two or more stations, acquire imaging data of the subject over the two or more stations, reconstruct images that correspond to each of the two or more stations, calculate an average intensity signal per slice within each of the reconstructed images, adjust intensity within at least one of the reconstructed images based on the calculated average intensity signal within each of the reconstructed images, and form a pasted image using the at least one of the reconstructed images having its intensity adjusted and another reconstructed image, having a boundary formed therebetween.

According to another aspect of the invention, a method of MR imaging includes obtaining diffusion-weighted MR imaging data of a subject from at least two stations, reconstructing images of the subject using the MR imaging data that correspond to the at least two stations, the images having a border formed therebetween, calculating an average intensity signal per slice within the reconstructed images to determine a net intensity offset between the reconstructed images, offsetting intensity of pixels within at least one of the reconstructed images based on the determined net intensity offset, and forming a pasted image using the reconstructed images, wherein at least one of the reconstructed images includes the at least one reconstructed image having had its pixel intensity offset.

According to yet another aspect of the invention, a computer readable storage medium having stored thereon a computer program comprising instructions, which, when executed by a computer, cause the computer to execute a diffusion-weighted imaging pulse sequence to acquire MR data from a subject over two or more stations, acquire imaging data of the subject over the two or more stations, reconstruct images of each of the two or more stations using the acquired imaging data, calculate an average intensity signal per slice within each of the two or more stations using the reconstructed images, determine an amount of pixel intensity offset based on the calculated average intensity per slice, adjust intensity within at least one of the reconstructed images based on the pixel intensity offset, and form a pasted image using the at least one of the reconstructed images having its intensity adjusted and another reconstructed image, having a boundary formed therebetween.

Various other features and advantages will be made apparent from the following detailed description and the drawings.

### BRIEF DESCRIPTION OF THE DRAWINGS

The drawings illustrate embodiments presently contemplated for carrying out embodiments of the invention.

In the drawings:

FIG. 1 is a schematic block diagram of an MR imaging system for use with embodiments of the invention.

FIG. 2 is a pulse sequence diagram showing ideal gradient and RF waveforms for a single spin echo diffusion-weighted EPI (DW-EPI) scan.

FIG. 3 illustrates pasted images obtained at a number of stations along an axis of a subject, the images correctable according to embodiments of the invention.

FIG. 4 is a flowchart showing an image correction technique according to an embodiment of the invention.

FIG. 5 illustrates the pasted images of FIG. 3 and corresponding average and corrected average intensities within each station, according to an embodiment of the invention.

FIG. 6 illustrates scenarios A and B for determining image intensity offset that occurs at a boundary between stations, according to embodiments of the invention.

FIG. 7 illustrates overlapping data in two neighboring stations in order to illustrate a correlation-based mis-registration image correction, according to an embodiment of the invention.

FIG. 8 illustrates boundary pixels and corresponding pixel identifiers for data smoothing, according to an example of an embodiment of the invention.

### DETAILED DESCRIPTION

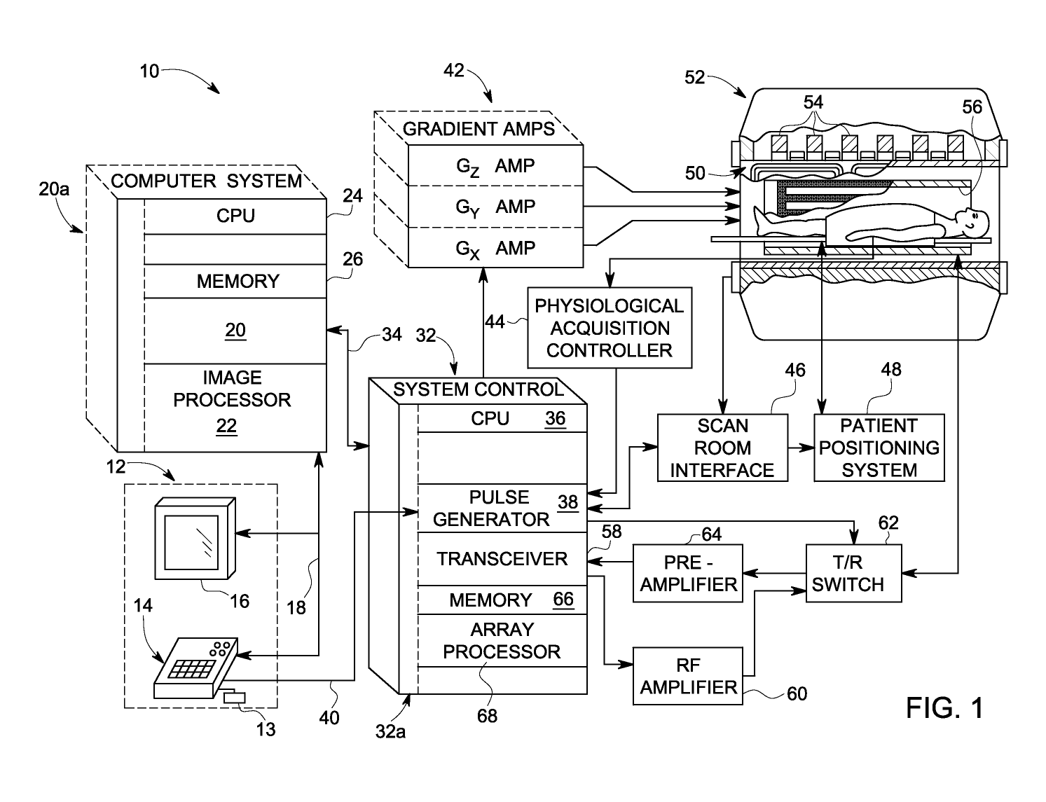

Referring to FIG. 1, the major components of a magnetic resonance imaging (MRI) system 10 incorporating an embodiment of the invention are shown. The operation of the system is controlled for certain functions from an operator console 12 which in this example includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through a backplane 20a. These modules include an image processor module 22, a CPU module 24 and a memory module 26, known in the art as a frame buffer for storing image data arrays. The computer system 20 communicates with a separate system control 32 through a high speed serial link 34. The input device 13 can include a mouse, joystick, keyboard, track ball, touch activated screen, light wand, voice control, card reader, push-button, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a resonance assembly 52 which includes a polarizing magnet 54 and a whole-body RF coil 56. A transceiver module 58 in the system control 32 produces pulses which are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory. In response to commands received from the operator console 12 or as otherwise directed by the system software, this image data may be archived in long term storage or it may be further processed by the image processor 22 and conveyed to the operator console 12 and presented on the display 16.

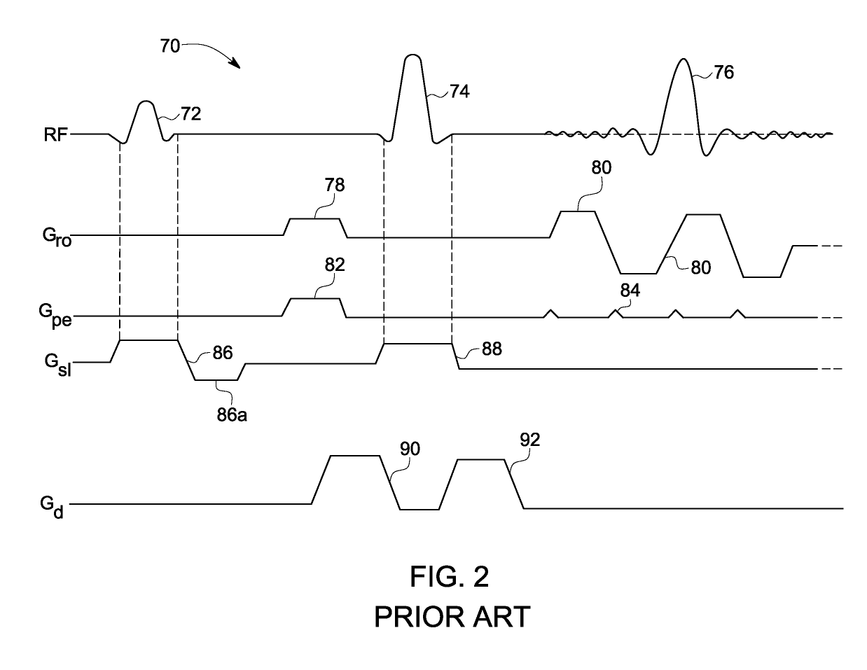

Referring to FIG. 2, a diffusion-weighted EPI (DW-EPI) pulse sequence 70 is shown including 90° and 180° RF pulses 72 and 74, respectively. RF pulses 72, 74 can be transmitted by RF coil 56 to generate an echo signal 76, which can be encoded with spatial information. Echo signal 76 can also be received by coil 56 or by another coil, such as a surface coil, for use in reconstructing an image. To spatially encode echo signal 76 in accordance with echo planar imaging, the sequence shown in FIG. 2 further includes read-out, phase-encoding, and slice-selection gradients Gᵣₒ, Gₚₑ, and Gₛₗ, respectively. Readout gradient Gᵣₒ comprises a pre-phasing pulse 78 and read-out pulses 80. Similarly, phase-encoding gradient Gₚₑ comprises a pre-phasing pulse 82 and phase-encoding pulses 84. Slice-selection gradient Gₛₗ comprises slice selection pulses 86 for the 90° RF pulse 72 and 88 for the 180° RF pulse 74, as well as 86a for slice refocusing.

Still referring to FIG. 2, there is shown diffusion-weighting gradient Gd, used in a diffusion-weighted EPI scan. Diffusion-weighting gradient Gd comprises two equivalent trapezoidal pulses 90 and 92, placed at either side of the 180° RF pulse 74. Note that in general, Gd can contain components in the read-out, phase-encoding, and slice axes. The pulse sequence illustrated in FIG. 2 is called the single spin echo or Stejkal-Tanner DW-EPI sequence. Note that the invention also applies to other DW-EPI sequences, such as dual spin echo (also called twice-refocused) and stimulated echo DW-EPI sequences.

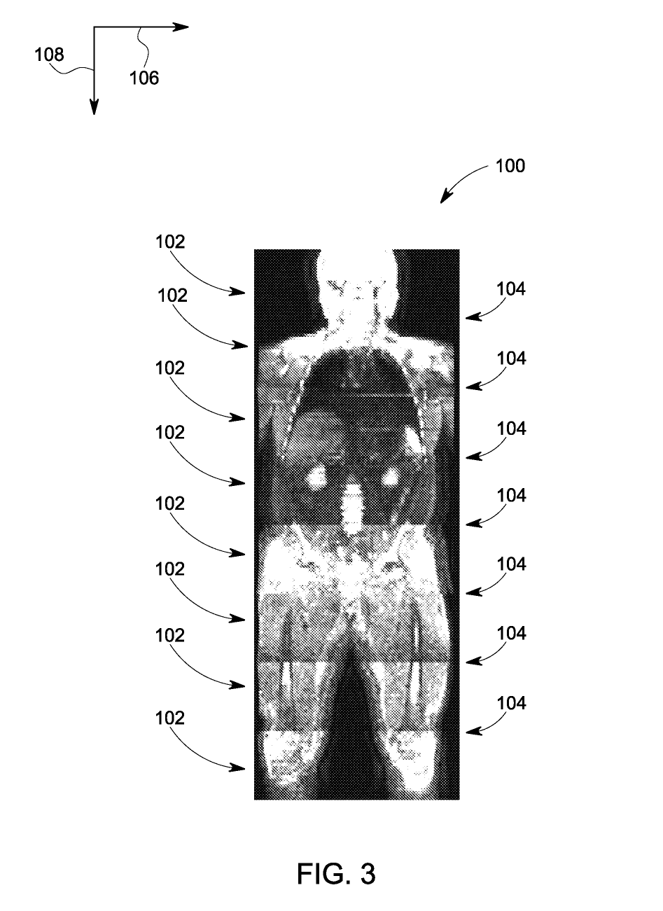

As known in the art, WB-DWI images may be obtained using the exemplary diffusion-weighted EPI pulse sequence as illustrated in FIG. 2 and using the exemplary imaging system as illustrated in FIG. 1. A single preliminary image 100 is formed from images 102 that are pasted (eight in the embodiment illustrated in FIG. 3), resulting in multiple stations of images having station boundaries 104 therebetween. As commonly known in the art, image 100 illustrates a coronal view of the object, having a readout direction 106 and a slice or transverse direction 108. In/out of image 100 corresponds to a phase-encoding direction, as also commonly known in the art. Similarly, although not illustrated, sagittal images may be generated along the phase-encoding direction as well, generated from pasted images from multiple stations and having boundaries therebetween as well.

As stated, such images may include 1) geometric discontinuities at station boundaries 104 due to the different B0 offset field that different stations face, and the eddy current and B0 related image distortion, 2) intensity discontinuities between stations 102 due to the sensitivity of RF pulses relative to B0 field offset and/or different transmit gain, and 3) image blurring or ghosting due to eddy current induced mis-registration. The discontinuities and blurring may be distinct and may occur in either the sagittal plane or the coronal plane, or both.

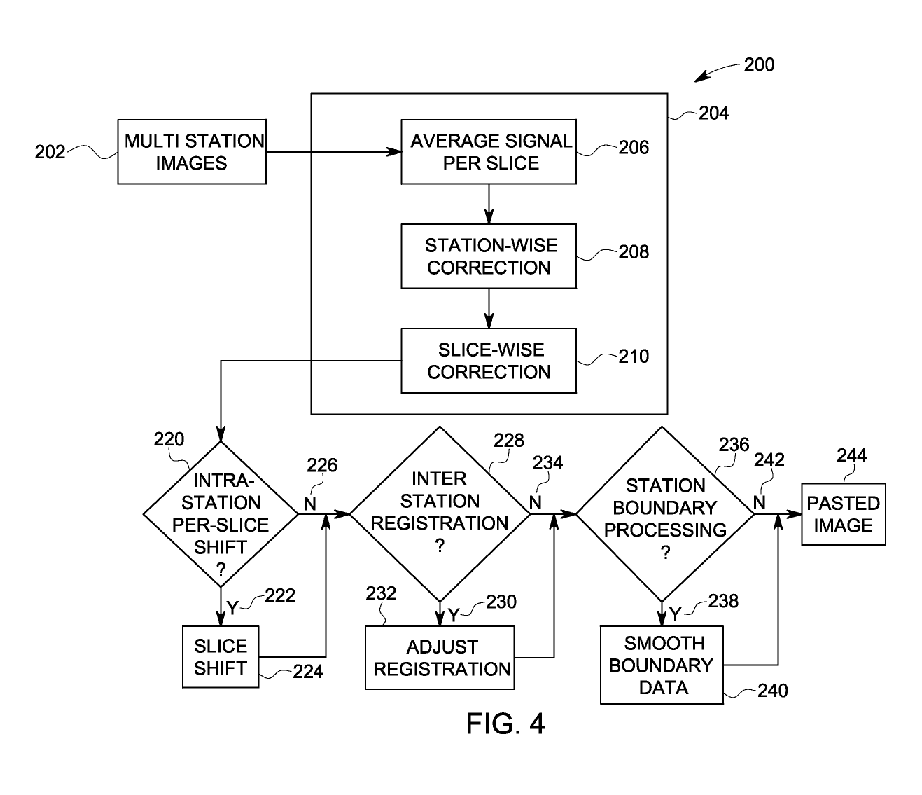

Thus, according to embodiments of the invention, the original multistation images (usually in axial planes) may be post-processed according to the flowchart illustrated in FIG. 4 to improve coronal and sagittal images. Referring to FIG. 4, flowchart 200 begins at step 202 with acquisition of multistation images which, as illustrated FIG. 3, includes images obtained at eight stations. Further, according to the illustrated embodiment, each image is comprised of 22 slices of image data. However, it is contemplated that more or less than eight stations of data may be acquired and reconstructed according to the invention. It is further contemplated that more or less than 22 slices of image data may be obtained per station, according to the invention. Image data is acquired on system 10 of FIG. 1 by executing a diffusion-weighted imaging scan comprising applying a DW-EPI pulse sequence to acquire MR data from an imaging subject over two or more stations, and acquiring imaging data of the subject over the two or more stations.

Image intensity correction is performed at step 204 on the multistation images in a number of substeps as illustrated therein. At a high level and as will be further illustrated, step 204 includes first calculating an average per slice 206, applying a station-wise intensity correction 208, and applying a slice-wise intensity correction 210.

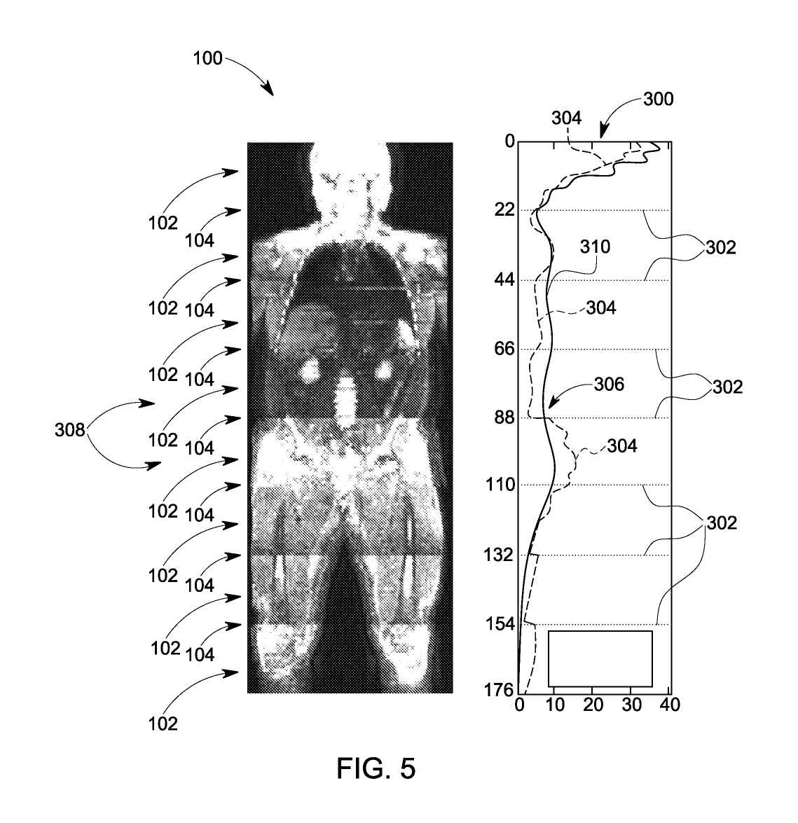

Data within each station is first averaged at step 206. As can be seen, a number of average intensity discontinuities can occur, which manifest themselves as distinct intensity differences between stages, as illustrated in FIG. 5. Referring to FIG. 5 for illustration of image intensity correction of step 204, single preliminary image 100 of FIG. 3 is again illustrated having images 102 and boundaries 104 therebetween. FIG. 5 also includes an intensity map or illustration 300 having boundaries 302 that correspond to boundaries 104 of FIG. 3. Intensity map 300 is obtained by computing an average pixel intensity within each slice of the image, as illustrated in average uncorrected curves 304 and image intensity is normalized or otherwise corrected by 1) adjusting pixel intensity of the stations 102 based on the average pixel intensity (i.e., station-wise, step 208) and 2) adjusting pixel intensity within each of the stations 102 based on a curvefit of the average pixel intensity data (i.e., slice-wise, step 210).

As can be seen in FIG. 5, intensity discontinuities may occur at boundaries 104 between stations 102 that can be caused by residual eddy current, B0 inhomogeneity and the like. Intensity discontinuities manifest themselves as a discontinuity 306 that occurs at slice 88, as one exemplary location in the illustrated example. Discontinuity 306 also manifests itself as a sharp and distinct change in general intensity between neighboring stations 308 in the coronal view 100. As such, according to the invention, intensity correction between stations 308 and within stations 308 is implemented in order to smooth the transition and generally apply a normalized intensity level to each slice within stations 102 in image 100. Thus, according to the invention, a station-wise correction is first applied to all slices within each station to eliminate the sharp discontinuities that can occur between stations (step 208), and individual slices are corrected within the stations of images 102 based on a curvefit of the intensity data (step 210).

Referring still to FIG. 5, an average intensity curve 310 is shown illustrating smooth transitions that occur between stations 102 and at boundaries 104. Average intensity curve 310 also illustrates intensity smoothing within stations 102, as will be illustrated. As can be seen, once average intensity curve 310 is generated, a varying amount of intensity is thereby present between the averaged curve 310 and the average uncorrected curves 304, which is then applied per slice, as will be further discussed.

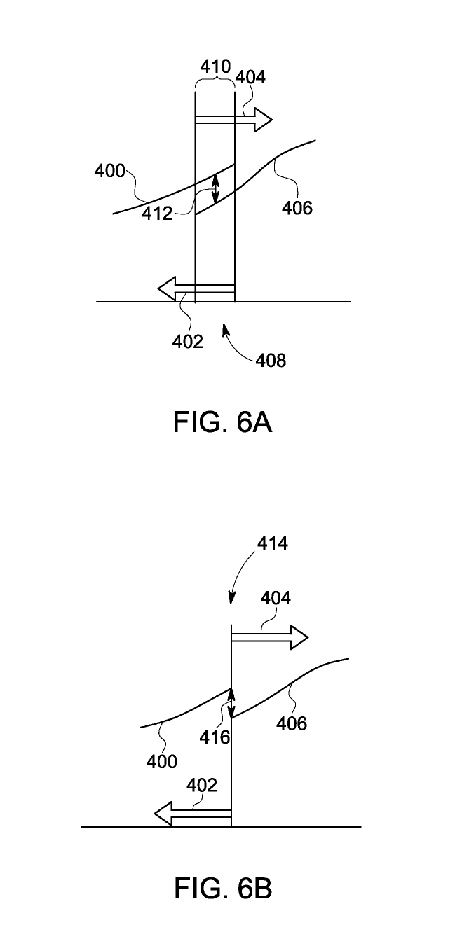

Step 208 of FIG. 4, station-wise correction of pixel intensity, is performed by first determining a correction coefficient between stations. The correction coefficient is based on an amount of intensity difference between stations based on the average signal per-slice intensity calculated at step 206. Station-wise correction 208 is performed by first determining whether an overlapping amount of data has been acquired between stations 102 and more particularly at their boundaries 104. According to the invention, pixel data at stations 102 may be obtained such that overlap at boundaries 104 occurring therebetween either does or does not occur (e.g., the images abut one another). Referring to FIG. 6 for illustration, two scenarios (A and B) are shown in order to illustrate how data intensity may be offset, depending on how the image data was obtained.

Referring first to FIG. 6A, a portion of a first station average intensity image data 400 is shown in an example that represents a portion of a first station image 402, and a portion of a second station image 404 is shown in the example that represents a portion of a second set of average image data 406. That is, arrows are shown illustrating first station image 402 and second station image 404, and first and second station images 402, 404 correspond to two of the station images 102 as discussed with respect to FIG. 3. It is to be understood that the illustrated first and second average intensity data 400, 406 represents only a portion of data in each of their respective images 402, 404, and that the data actually extends throughout each station and throughout multiple stations, once pasted together, as illustrated in FIG. 5.

As can be seen, images 402, 404 have a border 408 formed therebetween (corresponding to one of borders 104 of FIG. 5), having an overlap 410. Average intensity image data from each image 402, 404 that occurs in overlap 410, as well as data extending in each direction corresponding to each image 402, 404, may be used to correct image intensity between stations, as will be discussed. Referring still to FIG. 6A, data 400 is curvefit and data 406 is curvefit, each having data in overlap 410 and extending a portion into their respective image 402, 404. In one embodiment, all average data within each respective image 402, 404 is used to curvefit the image data. In curvefitting data 400, 406 as discussed, it is contemplated that any known curvefit routine may be implemented, including but not limited to a spline fit, a polynomial, etc. . . . as is commonly known in the art. As can be seen, a difference 412 occurs that can thereby be ascertained based on the curvefit from both images 402, 404. As such, difference 412 represents a difference that can be used to obtain a station-wise correction that is applied to pixel data within images 402, 404.

Similarly, FIG. 6B illustrates an example wherein there is essentially no overlap that occurs between images 402, 404 (e.g., the images abut one another). That is, border 414 is formed in this scenario in which no overlap (such as what occurred as overlap 410 in FIG. 6A) occurs. Thus, in this example and as with FIG. 6A, data 400, 406 may be curvefit, but in this case no overlapping data has been obtained, in order to determine a difference 416 that can be used to obtain a station-wise correction that is applied to pixel data within images 402, 404.

That described with respect to FIGS. 6A and 6B is performed between all stations 102 and at boundaries 104. Once differences therebetween are determined, a correction coefficient is applied to the stations in the following fashion. For instance, in an example where no overlap occurs between stations 102 (FIG. 6B), difference 416 is obtained, representing a sharp discontinuity between stations. The correction coefficient to be applied is determined based on the difference 416 and a magnitude of curves 400, 406 that occurs at boundary 414. As an example and using simple numbers to illustrate this technique, if the magnitude of curve 400 is 1.0 (in arbitrary intensity units) and that of curve 406 is 0.8, difference 416 is thereby determined to be 0.2 as described in the above method. A correction coefficient to be applied to station 404 is thereby determined by calculating 1/0.8=1.25. That is, the correction to be applied to station 404 is determined by dividing the magnitude of image data 400 that occurs at boundary 414 and then multiplying that correction factor to all slices within station 404. In such fashion, curve 406 will shift up by a factor 1.25, in this example, causing curve 400 to continuously transition to curve 406. As such, a station-wise correction is applied to image 404.

Referring back to FIG. 5, the station-wise correction at step 208 just illustrated is applied to all stations, using correction coefficients that are determined between stations based on either FIG. 6A or 6B above, depending on whether overlap data has been acquired. Assume first that the correction described applies to the first image 102 that includes slices 1-22, and to its neighboring image 102 that includes slices 23-44. The correction coefficient determined for these two images is applied to the station comprised of slices 23-44, and all subsequent stations that include slices 45-176. The correction applied to the station that includes slices 23-44 is carried throughout the remainder of the stations as well. As such, any discontinuity at the border proximate slice 22 has been removed, but discontinuities may still exist and would still need correction at subsequent borders proximate slices 44, 66, 88, 110, 132, and 154. According to the invention, a station-wise correction is again determined for the stations that border proximate to slice 44 (requiring another correction factor to be determined based on the stations to either side of slice 44), and then applied to subsequent stations having borders proximate slices 66, 88, 110, 132, and 154. The process continues until a station-wise correction has been applied to all borders. Thus, in summary, a station-wise correction is determined at border corresponding to slice 22, and applied at all subsequent borders. A station-wise correction is determined at the next border corresponding to slice 44, and applied to all subsequent borders. The process continues throughout all stations, resulting in continuous transitions at each border.

After completion of all borders between stations, station-wise correction 208 is complete and slice-wise correction is performed at step 210 of FIG. 4. That is, stations 104 of FIG. 5 have been offset from one another such that data is continuous from station to station at each of the borders 104. At step 210 data is also corrected by curvefitting the data within each station. That is, although a curvefitting step was performed in order to obtain correction coefficients at step 208, curvefitting is also done for slice-wise correction at step 210 as well in order to smooth data throughout all stations 102. The result of the station-wise correction at step 208 above, as well as the curvefitting within each station, is curve 310 of FIG. 5. Once curve 310 is obtained, a slice-wise correction is obtained based on the ratio between curve 310 and curve 304. That is, slice-wise correction 210 is applied per slice and based on the ratio that is measured between curves 310 and 304 per slice. Thus, slice-wise correction 210 includes applying a correction per slice that is determined as the magnitude of the ratio of curves 310 and 304 that occur at that given slice.

Thus, in summary and referring back to step 204 of FIG. 4, image intensity correction is performed on the multistation images in a number of substeps that include first determining an average intensity per slice at step 206, performing a station-wise correction at step 208, and performing a slice-wise correction at step 210.

Referring still to FIG. 4, once intensity is adjusted in the overall step 204, further additional post-processing steps may be applied to the data in order to improve the final pasted image. Thus, step 220 illustrates an intra-station per-slice assessment. Step 220 is an optional step that is performed based on whether the multistation images were obtained and corrected prior to implementation of the post-processing steps described herein.

As known in the art, non-phase-encoded reference data is in general available before an actual EPI data acquisition to estimate phase correction coefficients. By inspecting the overall phase angle across different echoes, a B0 offset is derived that is experienced by the EPI echo train from the same reference data. Details are as follows: Denote X as the readout axis (assumed to be a horizontal direction), and Y as the phase-encoding (i.e., echo index) axis (assumed to be vertical). EPI reference data is first converted to the image domain by performing an inverse Fourier transform along X. Phase angles all the even (or all the odd) echoes are taken and unwrapped along Y independently for each X, which is known in the art as the Ahn and Cho method. A linear fit along the Y direction is done on the phase angles of even echoes to obtain the phase slope sn(z), wherein n is the X index and Z is the slice direction.

The X dependent, B0 induced frequency offset fn(z) is readily available via: fn(z)=sn(z)/(2π·Tesp) where Tesp is the echo spacing. To increase robustness to noise (especially for slices with little tissue), a projection is obtained of the magnitude data along Y, and then threshold the resulting magnitude (e.g., setting the threshold to 5% of the maximum value, as an example) to provide a mask on X. The fn(z)'s that are included in the mask are averaged to provide a mean frequency offset estimate for a given slice location. Finally, polynomial or other known fitting is performed on the frequency offset along the slice direction to ensure smooth slice-to-slice intensity transition. The frequency offset estimates are obtained after the reference scan but before the actual EPI scan, and the EPI pulse sequence reads in the frequency offsets and adjusts the center frequency for each slice.

As such, above is described a known pre-processing method that may be used to correct B₀ induced signal loss using EPI reference data. According to the invention, if such a step is performed, then a reference scan may already be existent and available for performing step 220 of FIG. 4. That is, because a mask having a mean frequency offset estimate at each pixel was obtained as a pre-processing step, such may also be applied as a post-processing step that is assessed at step 220. Thus, if the above known pre-processing method has been used to correct B₀ induced signal loss using EPI reference data 222, then an intra-station per-slice slice shift correction is applied at step 224. If no pre-processing step has been performed 226, then intra-station correction is not applied as a post-processing step.

As step 228, image 100 is assessed to determine whether an inter-station registration will be performed. Mis-registration between image stations 102 can occur in the coronal view (such as that illustrated in FIG. 3) and along the transverse direction thereof (commonly known in the art as the readout direction). Mis-registration between image stations 102 can also occur in a sagittal view (not shown) and along a transverse direction thereof (commonly known in the art as the phase direction). If such mis-registration is evident 230, then registration between stations is implemented at step 232, according to the invention. Mis-registration may be corrected or adjusted according to at least two methods, depending on whether station-station overlap has occurred in the measured data or not. That is, referring back to step 208, it was determined whether station-station overlap was present corresponding to FIG. 6. As such, according to the invention, a mis-registration correction between stations may be obtained using A) correlation-based correction, or B) a mutual information-based correction.

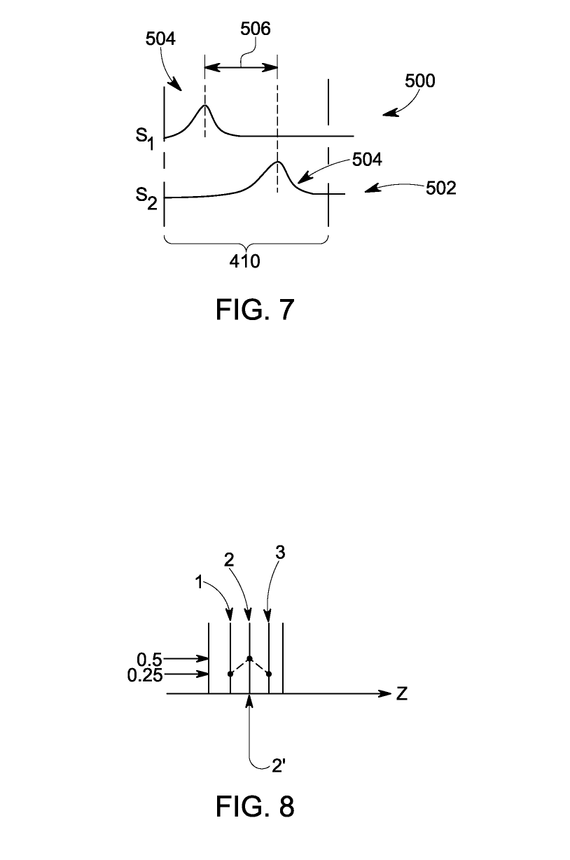

A) Mis-registration correction—correlation-based. According to this embodiment, as illustrated in FIG. 7, overlapping data has been acquired having an overlap 410, corresponding to scenario A of FIG. 6. The data represented, S₁ 500 and S₂ 502 illustrates exemplary imaging data having a feature 504 that is offset by a distance Δt 506. That is, feature 504 is an exemplary feature that is present in each image dataset of neighboring stations. The goal is to obtain offset distance Δt 506, represented as the distance between peaks of each feature 504, such that station images align. Accordingly, offset distance Δt 506 is obtained using overlap data with the following equation:

$$Δ t {\vert}_{max} = {max}_{Δ t} {\sum }_{t} \vert {s}_{2} ( t + Δ t ) * {s}_{1} ( t ) \vert ; \qquad Eqn . 1.$$

As such, an amount Δt may be numerically determined in order to shift s₂ by multiplying point-by-point, and sum, to maximize as a function of Δt.

B Mis-registration correction—mutual information-based. According to this embodiment, correction may be determined when no overlapping data has been acquired, corresponding to scenario B of FIG. 6. That is, the mutual information or transinformation of the two neighboring datasets may be used to determine the mis-registration correction.

As known in the art, the mutual information of two discrete random variables X and Y can be defined as:

$$I ( X ; Y ) = {\sum }_{y ∈ Y} {\sum }_{x ∈ X} p ( x , y ) log ( \frac{p ( x , y )}{p ( x ) p ( y )} ) , \qquad Eqn . 2 ,$$

where p(x,y) is the joint probability distribution function of X and Y, and p(x) and p(y) are the marginal probability distribution functions of X and Y respectively. In the case of continuous random variables, the summation is matched with a definite double integral:

$$I ( X ; Y ) = {\int }_{Y}^{ } {\int }_{X}^{ } p ( x , y ) log ( \frac{p ( x , y )}{p ( x ) p ( y )} ) d x d y , \qquad Eqn . 3 ,$$

where p(x,y) is now the joint probability density function of X and Y, and p(x) and p(y) are the marginal probability density functions of X and Y respectively.

The aforementioned mutual information-based discussion is known in the art and forms the basis on which this step is performed. When significant station overlap is available, registration can be done in the sagittal plane. And, although registration can be done in multiple dimensions, 1D registration along the phase-encoding axis (anterior-posterior direction) may be preferred because 1D registration tends to be more robust and efficient.

Thus, according to the invention and referring back to FIG. 4, at step 228 mis-registration is assessed between stations and if adjustment is performed, it is correlation-based or mutual information-based, depending on whether overlap data exists between stations. Whether inter-station registration correction is performed 230 or not 234, then station boundary processing is next assessed at step 236. At this step, station boundary or overlapping slices are optionally smoothed in the superior-anterior direction to further reduce any remaining and slight residual discontinuities.

According to this embodiment, if boundary data is to be smoothed 238, then boundary data is smoothed at step 240 using a “linear kernel based” smoothing algorithm of overlapping or neighboring data. That is, data is smoothed using neighboring data in order to remove or reduce visual anomalies in the data in order to provide generally a better aesthetic appearance. As one example, referring to FIG. 8, proximate a boundary pixel, neighboring pixel data to either side of the pixel to be corrected may be used to smooth data in each cell. For instance, pixels “1”, “2”, and “3” may be used to re-calculate or smooth to determine pixel “2′”. Thus, according to one example, pixel 2′=0.5 X “2”+0.25 X “1”+0.25 X “3”. Each pixel may thereby be re-calculated using one pixel to either side (e.g., in a positive and a negative slice direction) of the pixel to be corrected. Further, it is contemplated that any number of pixels may be used to smooth or recalculate each pixel. Whether boundary data is smoothed 238 or not 242, images are pasted into a final whole body pasted image at step 244.

According to the invention, any combination of corrective steps disclosed herein may be applied to a pasted image. That is, any combination of steps 204, 220, 228, and 236 may be applied, regardless of whether the other steps have been performed, consistent with the discussion of each step.

A technical contribution for the disclosed method and apparatus is that it provides for a computer implemented method of correcting image pasting in diffusion-weighted echo planar imaging (EPI).

One skilled in the art will appreciate that embodiments of the invention may be interfaced to and controlled by a computer readable storage medium having stored thereon a computer program. The computer readable storage medium includes a plurality of components such as one or more of electronic components, hardware components, and/or computer software components. These components may include one or more computer readable storage media that generally stores instructions such as software, firmware and/or assembly language for performing one or more portions of one or more implementations or embodiments of a sequence. These computer readable storage media are generally non-transitory and/or tangible. Examples of such a computer readable storage medium include a recordable data storage medium of a computer and/or storage device. The computer readable storage media may employ, for example, one or more of a magnetic, electrical, optical, biological, and/or atomic data storage medium. Further, such media may take the form of, for example, floppy disks, magnetic tapes, CD-ROMs, DVD-ROMs, hard disk drives, and/or electronic memory. Other forms of non-transitory and/or tangible computer readable storage media not list may be employed with embodiments of the invention.

A number of such components can be combined or divided in an implementation of a system. Further, such components may include a set and/or series of computer instructions written in or implemented with any of a number of programming languages, as will be appreciated by those skilled in the art. In addition, other forms of computer readable media such as a carrier wave may be employed to embody a computer data signal representing a sequence of instructions that when executed by one or more computers causes the one or more computers to perform one or more portions of one or more implementations or embodiments of a sequence.

Therefore, according to an embodiment of the invention, an MRI apparatus includes a magnetic resonance imaging (MRI) system having a plurality of gradient coils positioned about a bore of a magnet, and an RF transceiver system and an RF switch controlled by a pulse module to transmit RF signals to an RF coil assembly to acquire MR images, and a computer programmed to execute a diffusion-weighted imaging pulse sequence to acquire MR data from a subject over two or more stations, acquire imaging data of the subject over the two or more stations, reconstruct images that correspond to each of the two or more stations, calculate an average intensity signal per slice within each of the reconstructed images, adjust intensity within at least one of the reconstructed images based on the calculated average intensity signal within each of the reconstructed images, and form a pasted image using the at least one of the reconstructed images having its intensity adjusted and another reconstructed image, having a boundary formed therebetween.

According to another embodiment of the invention, a method of MR imaging includes obtaining diffusion-weighted MR imaging data of a subject from at least two stations, reconstructing images of the subject using the MR imaging data that correspond to the at least two stations, the images having a border formed therebetween, calculating an average intensity signal per slice within the reconstructed images to determine a net intensity offset between the reconstructed images, offsetting intensity of pixels within at least one of the reconstructed images based on the determined net intensity offset, and forming a pasted image using the reconstructed images, wherein at least one of the reconstructed images includes the at least one reconstructed image having had its pixel intensity offset.

According to yet another embodiment of the invention, a computer readable storage medium having stored thereon a computer program comprising instructions, which, when executed by a computer, cause the computer to execute a diffusion-weighted imaging pulse sequence to acquire MR data from a subject over two or more stations, acquire imaging data of the subject over the two or more stations, reconstruct images of each of the two or more stations using the acquired imaging data, calculate an average intensity signal per slice within each of the two or more stations using the reconstructed images, determine an amount of pixel intensity offset based on the calculated average intensity per slice, adjust intensity within at least one of the reconstructed images based on the pixel intensity offset, and form a pasted image using the at least one of the reconstructed images having its intensity adjusted and another reconstructed image, having a boundary formed therebetween.

This written description uses examples to disclose embodiments of the invention, including the best mode, and also to enable any person skilled in the art to practice the embodiments of the invention, including making and using any devices or systems and performing any incorporated methods. The patentable scope of embodiments of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. An MRI apparatus comprising:
a magnetic resonance imaging (MRI) system having a plurality of gradient coils positioned about a bore of a magnet, and an RF transceiver system and an RF switch controlled by a pulse module to transmit RF signals to an RF coil assembly to acquire MR images; and
a computer programmed to:
execute a diffusion-weighted imaging pulse sequence to acquire MR data from a subject over two or more stations;
acquire imaging data of the subject over the two or more stations;
reconstruct images that correspond to each of the two or more stations;
calculate an average intensity signal per slice within each of the reconstructed images;
adjust intensity within at least one of the reconstructed images based on the calculated average intensity signal within each of the reconstructed images; and
form a pasted image using the at least one of the reconstructed images having its intensity adjusted and another reconstructed image, having a boundary formed therebetween.

2. The MRI apparatus of claim 1 wherein the computer is further programmed to perform a station-wise correction by being programmed to:
calculate a difference in magnitude of intensity proximate a border between two stations of reconstructed image data;
adjust image intensity data within one of the two stations of reconstructed images, and subsequent stations, based on the difference;
calculate another difference in magnitude of intensity proximate another border between two subsequent stations of reconstructed data; and
adjust image intensity data within one of the two subsequent stations, based on the another difference.

3. The MRI apparatus of claim 1 wherein the computer is further programmed to perform a slice-wise correction by being programmed to curvefit the calculated average intensity, determine a ratio per-slice between image data of the reconstructed images and the curvefit, and adjust the intensity per-slice based on a corresponding ratio.

4. The MRI apparatus of claim 1 wherein the computer is programmed to:
determine whether an overlap has occurred at the boundary between two of the two or more stations; and
curvefit average intensity per slice within each of the reconstructed images to determine a difference in magnitude of intensity between the two stations.

5. The MRI apparatus of claim 4 wherein:
if overlap has occurred between two of the stations, then the computer is programmed to use at least average slice data from each of the two stations within an overlap region at the boundary; and
if overlap has not occurred between two of the stations, then the computer is programmed to use average slice data proximate the boundary from each of the two stations.

6. The MRI apparatus of claim 1 wherein if there is mis-registration at the boundary between the reconstructed images, the computer is programmed to adjust registration of the reconstructed images in one of a coronal and a sagittal plane by applying an inter-station per-slice shift.

7. The MRI apparatus of claim 6 wherein, if the computer adjusts the registration between the reconstructed images, the computer is further programmed to adjust the registration by being programmed to:
apply a correlation-based shift if there is an image overlap at the boundary; or
apply a mutual information-based shift if there is not an image overlap at the boundary.

8. The MRI apparatus of claim 1 wherein the computer is programmed to:
prior to executing the diffusion-weighted imaging scan, obtain a reference scan at each station and estimate a frequency offset to correct, within each slice of each station, at least one of a tissue susceptibility and a B₀ field inhomogeneity when executing the diffusion-weighted imaging pulse sequence; and
apply an intra-station per-slice shift to the reconstructed images based on the reference scan.

9. The MRI apparatus of claim 1 wherein the computer is programmed to smooth data in the formed image by being programmed to recalculate image slice information in the pasted image and at the boundary based on neighboring slice data in both a positive and a negative slice direction.

10. A method of MR imaging comprising:
obtaining diffusion-weighted MR imaging data of a subject from at least two stations;
reconstructing images of the subject using the MR imaging data that correspond to the at least two stations, the images having a border formed therebetween;
calculating an average intensity signal per slice within the reconstructed images to determine a net intensity offset between the reconstructed images;
offsetting intensity of pixels within at least one of the reconstructed images based on the determined net intensity offset; and
forming a pasted image using the reconstructed images, wherein at least one of the reconstructed images includes the at least one reconstructed image having had its pixel intensity offset.

11. The method of claim 10 comprising:
determining whether the border is formed of images that overlap one another to form the boundary, or whether the border is formed of images that abut one another to form the boundary;
curvefitting the average intensity within each of the images;
determining the net intensity offset based on a curvefit of the average intensity within each of the images;
calculating a station-wise correction coefficient based on the net intensity offset and based on a magnitude of the calculated intensity proximate where the net intensity offset is calculated; and
applying the station-wise correction coefficient to one of the images that forms the border and to subsequent images.

12. The method of claim 10 further comprising calculating a per-slice correction based on a curvefit of the average intensity, wherein offsetting the intensity of the pixels comprises offsetting each slice based on a respective per-slice correction.

13. The method of claim 11 comprising:
if the images overlap to form the boundary, then the step of curvefitting comprises curvefitting using imaging data in each of the images that overlaps to form the boundary; or
if the images abut to form the boundary, then the step of curvefitting comprises curvefitting using imaging data in each of the images that abut one another.

14. The method of claim 10 comprising:
determining whether image mis-registration has occurred between the images at the boundary in at least one of a coronal and a sagittal plane;
adjusting image registration between the images using one of:
applying a correlation-based shift if there is an image overlap at the boundary; and
applying a mutual-information based shift if images that form the boundary abut one another.

15. The method of claim 10 comprising:
obtaining a reference scan of each of the at least two stations;
estimating a frequency offset within each reconstructed image to correct, within each station, at least one of a tissue susceptibility and a B₀ field inhomogeneity when executing the diffusion-weighted MR imaging scan; and
applying an intra-station per-slice shift to the reconstructed images based on the reference scan.

16. The method of claim 10 comprising:
recalculating image slice information in the pasted image proximate a boundary between two of the reconstructed images based at least on neighboring pixel data in at least one of a positive and a negative slice direction; and
reforming the pasted image using the recalculated image slice information.

17. A computer readable storage medium having stored thereon a computer program comprising instructions, which, when executed by a computer, cause the computer to:
execute a diffusion-weighted imaging pulse sequence to acquire MR data from a subject over two or more stations;
acquire imaging data of the subject over the two or more stations;
reconstruct images of each of the two or more stations using the acquired imaging data;
calculate an average intensity signal per slice within each of the two or more stations using the reconstructed images;
determine an amount of pixel intensity offset based on the calculated average intensity per slice;
adjust intensity within at least one of the reconstructed images based on the pixel intensity offset; and
form a pasted image using the at least one of the reconstructed images having its intensity adjusted and another reconstructed image, having a boundary formed therebetween.

18. The computer readable storage medium of claim 17 wherein the computer is further programmed to curvefit the calculated average intensity, and adjust the intensity per-slice based on a corresponding ratio derived from a ratio determined per-slice between the reconstructed image data and the curvefit intensity.

19. The computer readable storage medium of claim 17 wherein the computer is further caused to:
determine whether an overlap has occurred at the boundary between two of the two or more stations; and
curvefit average intensity per slice within each of the reconstructed images.

20. The computer readable storage medium of claim 17 wherein:
if image overlap has occurred between two of the stations, then the computer is programmed to use at least average slice data from each of the two stations within an overlap region at the boundary; and
if overlap has not occurred between two of the stations, then the computer is programmed to use average slice data proximate the boundary from each of the two stations.

21. The computer readable storage medium of claim 17 wherein if there is mis-registration at the boundary between the reconstructed images, the computer is programmed to adjust registration of the reconstructed images in one of a coronal and a sagittal plane.

22. The computer readable storage medium claim 21 wherein, if the computer is programmed to adjust the registration between the reconstructed images, the computer is further programmed to:
apply a correlation-based shift if there is an image overlap at the boundary; or
apply a mutual information-based shift if there is not an image overlap at the boundary.

23. The computer readable storage medium of claim 17 wherein the
computer is programmed to:
prior to executing the diffusion-weighted imaging scan, obtain a reference scan at each station and estimate a frequency offset to correct, within each station, at least one of a tissue susceptibility and a B₀ field inhomogeneity when executing the diffusion-weighted imaging pulse sequence; and
apply an intra-station per-slice shift to the reconstructed images based on the reference scan.

24. The computer readable storage medium of claim 17 wherein the computer is programmed to smooth data in the formed image by being programmed to recalculate image slice information in the pasted image and at the boundary based on neighboring slice data in both a positive and a negative slice direction.
